(19) United States
(12) Patent Application Publication
(10) Pub. No.: US 2025/0077728 A1
(43) Pub. Date: Mar. 6, 2025

(54) MANUFACTURING DATA ANALYSIS SYSTEM ASSISTANT

(71) Applicant: Lumafield, Inc., Cambridge, MA (US)

(72) Inventors: Andreas Linas Bastian, San Francisco, CA (US); Alan Paul Kalbfleisch, San Francisco, CA (US); Katayun J. Kamdin, Oakland, CA (US); Sebastian Gerd Ahling, Medford, MA (US); Branden Alexander Lisk, Cambridge, MA (US); Zachary J. Weiss, Newton, MA (US); Daniel Pipe-Mazo, Redondo Beach, CA (US); Eduardo Jesus Torrealba, III, Cambridge, MA (US)

(21) Appl. No.: 18/821,714

(22) Filed: Aug. 30, 2024

Related U.S. Application Data
(60) Provisional application No. 63/535,409, filed on Aug. 30, 2023.

(51) Int. Cl. G06F 30/17

(52) U.S. Cl. CPC G06F 30/17

(57) ABSTRACT

Provided herein are methods, apparatuses, computer program products, and systems for a manufacturing data analysis system assistant. One method can include receiving, by an agent of a manufacturing data analysis system and from a user interface of the manufacturing data analysis system, an input related to manufacturing data; generating, by the agent, a prompt input based on context information related to the manufacturing data and a task identified for the input; providing, by the agent, the prompt input to a large language model (LLM); receiving, by the agent and from the LLM, a response that is based on the prompt input; and providing, by the agent, the response for display in the user interface.

### CROSS-REFERENCE TO RELATED APPLICATIONS

This patent application claims priority to and the benefit of U.S. Provisional Patent Application No. 63/535,409, filed on Aug. 30, 2023, which is incorporated herein by reference in its entirety.

### BACKGROUND

Some manufacturing software can visualize, analyze and share manufacturing data. The manufacturing data can include computer aided design (CAD) of a part, an image of a part, or a two-dimensional or three-dimensional scan of a part, and so on. Through a user interface, a user of the software can review the manufacturing data, find defects, compare different parts, and make design and manufacturing decisions.

A language model is a probabilistic model of a natural language that can generate probabilities of a series of words, based on text corpora in one or multiple languages it was trained on. Large language models (LLMs) use feedforward neural networks and transformers to analyze huge amounts of data, learning the patterns and connections between words and phrases.

LLMs are probabilistic models that do not inherently guarantee accurate predictions in response to requests for specific factual information. Additionally, much domain-specific factual information is not publicly available and is not included in a LLM's original training data. As a result, LLMs often struggle to deliver factually correct information on domain-specific queries.

### SUMMARY

This specification describes technologies relating to an agent/assistant of a manufacturing data analysis system, which helps users to analyze their data, answer manufacturing questions, and assist users with the manufacturing data analysis system. The agent uses one or more large language models and can be tightly integrated with the system's backend servers and frontend user interface. Users can interact with the agent in the context of a project or independent of a specific project. For example, they can click into a project in the system to open the agent and can then have a conversation with the agent about details of the project. As another example, from a graphical user interface (e.g., a homepage or the interface of a CT scanner) of the system, the user can open the agent and can have a conversation with the agent about multiple projects that belong to an organization.

The details of one or more embodiments of the subject matter described in this specification are set forth in the accompanying drawings and the description below. Other features, aspects, and advantages of the invention will become apparent from the description, the drawings, and the claims.

### BRIEF DESCRIPTION OF THE DRAWINGS

FIG. 1 shows an example of a manufacturing data analysis system.

FIG. 2 is a flowchart showing an example of operations performed by an agent of a manufacturing data analysis system.

FIG. 3 is a flowchart showing an example of a process to use tightly integrated tools of the manufacturing data analysis system.

FIG. 4 is a flowchart showing an example of operations performed by a stateless agent.

FIG. 5 is a flowchart showing an example of a process to use non-tightly integrated tools.

FIG. 6 is a swimlane diagram showing an example implementation of chat history, agent and a tightly integrated tool.

FIG. 7 shows an example of a custom vectorstore tool to disseminate institutional knowledge.

FIG. 8A is a flowchart showing an example of a process to limit the size of chat history.

FIG. 8B is a flowchart showing an example of a process to reduce the size of chat history using a large language model (LLM).

FIG. 9 shows an example user interface of a manufacturing data analysis system.

FIG. 10 shows an example implementation of a handler.

FIG. 11 shows an example database schema for the database tables for the chat context and chat messages.

Like reference numbers and designations in the various drawings indicate like elements.

### DETAILED DESCRIPTION

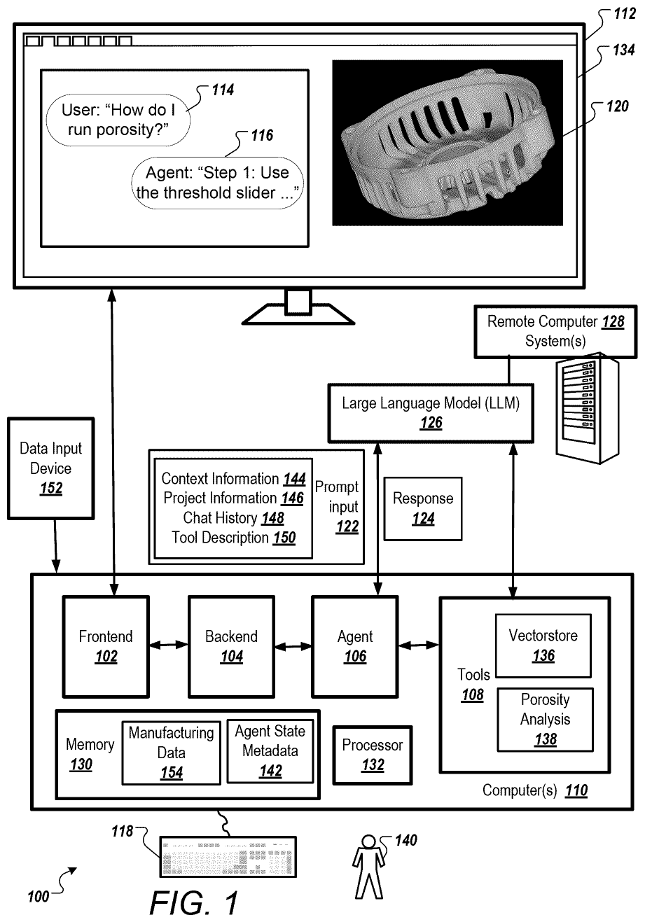

FIG. 1 shows an example of a manufacturing data analysis system 100. The manufacturing data analysis system 100 can be configured to visualize, analyze and share manufacturing data 154 generated during the design and/or manufacturing of a part. The manufacturing data 154 can be located in a memory 130, a long-term storage (e.g., a database or a hard drive), or a combination of both. Examples of possible types of manufacturing data include computer aided design (CAD) data, computer aided manufacturing (CAM) data, radiographs or reconstructions obtained from computed tomography (CT) scans of physical parts, meshes, images, (Portable Document Format) PDF drawings, and point clouds from various types of data input devices 152, such as scanners and sensors. For example, users of the system 100 can measure dimensions of a part or find pores and cracks in a part. In some implementations, the system 100 can be connected to, or can include a CT scanner, or the system 100 itself is a CT scanner system, and the system 100 can obtain CT scan data for a part from the CT scanner.

In some implementations, a user can upload manufacturing data obtained from other scanning systems. For example, meshes, point clouds, radiographs, Red Green Blue (RGB) images, Red Green Blue Depth (RGBD) images, CAD files can originate from other scanning systems, such as 3D scanners, optical comparators, profilometers, photogrammetry systems, LIDAR sensors, structured light scanners, laser line scanners, etc.

In some implementations, the manufacturing data analysis system can be a computed tomography (CT) system and the manufacturing data can include CT scan data for a part. X-Ray CT is a technique which can be used by manufacturers in order to determine the quality of the products which they produce. X-Ray CT is particularly useful to give manufacturers the ability to inspect certain parts of their products in a non-invasive, non-destructive fashion. The CT system can perform multiple computational steps including, but not limited to, storing the two-dimensional (2D) radiographs, generating a three-dimensional (3D) reconstruction from the 2D radiographs, storing the 3D reconstruction, and analyzing the 3D reconstruction so as to make decisions about the quality of a part or a product. Here, the CT scan data can refer to 2D or 3D radiographs, 2D or 3D reconstruction images, or combinations thereof.

The system 100 includes a frontend 102 that implements a user interface 134 and one or more workflows and displays the user interface 134 on a display device 112. The frontend 102 can be implemented in a web browser or in an application (App) that runs on a mobile device or another computing device or system. Through the user interface 134, a user of the system 100 can render a project 120, review the manufacturing data 154, find defects, compare different parts, and make design and manufacturing decisions. For example, a user can click into a project 120 in the system and can then review manufacturing data 154, such as CT scan data for a part. In some implementations, the frontend 102 can include a homepage or landing page of an App in the user interface 134. From the homepage or any suitable location in the App, the user can access one or more tools 108 available in the system 100.

The system 100 includes a backend 104. In some implementations, the frontend 102 and the backend 104 can be implemented in the same piece of software, e.g., for a wholly local application. The backend 104 includes the software that runs on a computer 110 (e.g., a server), that receives requests from the frontend 102, and contains the logic to send the appropriate data back to the frontend 102. In some implementations, the backend 104 includes software that runs on a cloud server. In some implementations, the backend 104 includes software that runs on a local server. In some implementations, the system is accessible by the user through a website, and the frontend 102 refers to a frontend of the website and the backend 104 refers to the backend of the website. In some implementations, the backend can be implemented as a RESTFul API, i.e., an application programming interface that conforms with the Representational State Transfer (REST) architecture, where the RESTFul API interacts with a database and other microservices.

The system 100 includes one or more tools 108. Here the tools 108 refer to program functionality of a software or a system. Users of the system 100 can perform analysis of manufacturing data 154 using the one or more tools 108. Examples of the one or more tools 108 include visualization tools, measuring tools, defect detection and analysis tools, comparison tools, collaboration and data sharing tools. For example, the tools 108 can include a porosity analysis tool 138 that can find pores in CT scan data for a part and provide quantitative measurements of the pores.

In some implementations, the agent can access the tools 108 through application programming interface (API) calls. In some implementations, the system can implement one or more tools in the agent, e.g., at the code level instead of at the API level in the backend. If there is no direct need to involve the backend when using a particular tool, the system can implement the particular tool at the code level in the agent. For example, the tools 108 can include a vectorstore tool 136 storing embedding data and performing vector search. The vectorstore tool 136 can be implemented at the code level in the agent. The embedding data can include embedding vectors of design and manufacturing documentation, user interface documentation, CT scanning documentation, or user-specific documentation. The agent can invoke the vectorstore tool 136 to obtain an answer to a question, e.g., to retrieve one or more pieces of text related to the question by searching in the embedding data using a similarity metric.

A tool can be defined using at least one of: (1) a name for the tool; (2) a description of the tool which is passed to the agent in the agent prompt; or (3) the functionality of the tool itself. If a tool is defined using (2) a description of the tool which is passed to the agent in the agent prompt, the agent 106 can generate the prompt input based on the context information and description information of the tool and can provide the prompt input to the LLM. The functionality for the tool can be implemented in either a form (a) which can be called and will return an answer to the agent immediately, or a form (b) in which the agent needs to signal to the system 100 that it needs an analysis to be run, or a model to be shown to the user to solicit input, etc.

The system 100 includes an agent 106 that interacts with a generative language model, e.g., a large language model (LLM) 126, and the backend 104 of the manufacturing data analysis system 100. In some implementations, the frontend 102, the backend 104, and the agent 106 can be on separate computers. In some implementations, at least two of the frontend 102, the backend 104, and the agent 106 can be on a shared computer. The agent 106 helps users of the system 100 to analyze manufacturing data, answer manufacturing questions, and assist users with the manufacturing data analysis system 100. In some implementations, the user interface of the agent is chat-based, and users can make conversations with the agent. In some implementations, the user interface of the agent can be speech/voice based and users can have a voice conversation with the agent. In some implementations, the user interface of the agent can be video based and users can interact with an animated assistant who speaks with the users. In some implementations, the agent can be integrated into the user interface of the system, where users can interact with the agent by clicking through the user interface.

In some implementations, the agent can run in the context of a single project that is currently open in the system. In some implementations, the agent can run outside of the scope of a project, such as from the homepage/landing page or any suitable location in an App. For example, the agent can handle the knowledge tools (e.g., manufacturing knowledge, help docs) without needing a specific project to reference to. In some implementations, the agent can access all of the projects a user has in their organization and can query across all of them.

The agent 106 can receive a query input related to manufacturing data, e.g., not related to a project, or related to one or more projects from the user interface. The agent can generate a prompt input 122 based on context information 144 related to the manufacturing data and a task identified for the query input. In some implementations, the prompt input 122 can further include one or more of the following: project information 146 (e.g., of the current project 120), chat history 148, or tool description 150 (e.g., of the one or more tools 108). The agent 106 can provide the prompt input 122 to a LLM 126 and obtain a response to the query input. The agent can receive a response 124 from the LLM 126. The agent provides the response 124 (through the backend and frontend) in the user interface. In some implementations, the system 100, or a machine learning training system, can provide the prompt input 122 to the LLM 126 to further train the LLM 126 and obtain a response to the query input in light of that further training. For example, when an LLM uses a Generative Pre-trained Transformer (GPT) model, the training of the LLM can include both (i) pre-training to learn the general characteristics of the language, and then (ii) fine-tuning to learn a specialized task or subject area.

For example, after opening the CT scan data 154 in a CT project 120 in the user interface 134, a user can enter a query 114, “How do I run porosity?”, in a chat box. The agent can identify a task for the input, e.g., that the user is interested in learning about the porosity analysis tool 138. The agent can generate a prompt input 122 based on context information related to the CT project 120 and the identified task. The agent can provide the prompt input 122 to the LLM 126 and can receive a response 124 from the LLM 126. The response 124 can include instructions on how a user can use the porosity analysis tool. The agent can provide the response for display in the user interface 134, such as displaying a message 116 that includes “Step 1: Use the threshold slider . . . ”

A generative language model, e.g., the LLM 126, is a probabilistic model of a natural language that can generate probabilities of a series of words, based on text corpora in one or multiple languages it was trained on. The LLM 126 can include feedforward neural networks and/or transformers that have a large size and are trained on huge amounts of data to perform analysis on the patterns and connections between words and phrases. Because of the large size, the LLM 126 typically runs on remote computer system(s) 128 (e.g., in the cloud). The agent 106 can access the LLM 126 through API calls.

In some implementations, the system can include an LLM that has been trained with the concept of function calls and the LLM can be configured to access tools which can be utilized to help the agent 106 perform tasks. Therefore, the LLM can interact with external data sources, knowledge bases and APIs seamlessly as it works to solve a general question which is posed. For example, the LLM 126 can include a Generative Pre-trained Transformer (GPT) model with function calling capability, such as the GPT-4 software service available from OpenAI OpCo, LLC, of San Francisco, California.

In some implementations, the system 100 can include multiple LLMs that interact with the agent 106 and the tools 108. For example, the agent 106 can use a first LLM, such as the GPT-4 software service. The vectorstore tool 136 can use an embedding LLM to generate embedding vectors. The vectorstore tool 136 can use another LLM to summarize the information found via embedding vector search, such as the GPT-3.5 software service or the GPT-4 software service.

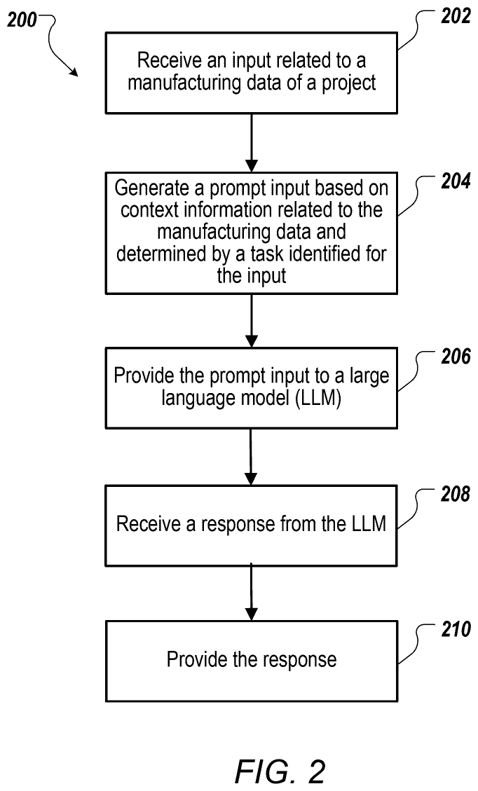

The system 100 can be implemented in at least one computer 110 that includes at least one memory 130 and at least one processor 132. Processor 132, memory 130, and any subset thereof, can be configured to provide the algorithmic functionality corresponding to the various blocks of FIGS. 2-11 in addition to being configured to provide manufacturing data visualization, analysis, and sharing functionality.

Processor(s) 132 can be embodied by any computational or data processing device, such as a central processing unit (CPU), application specific integrated circuit (ASIC), or comparable device. The processor(s) 132 can be implemented as a single controller, or a plurality of controllers or processors.

The memory 130 can be fixed or removable. The memory 130 can include computer program instructions or computer code contained therein. Memory 130 can be any suitable storage device, such as a non-transitory computer-readable medium. The term “non-transitory,” as used herein, can correspond to a limitation of the medium itself (i.e., tangible, not a signal) as opposed to a limitation on data storage persistency (e.g., random access memory (RAM) vs. read-only memory (ROM)). A hard disk drive (HDD), random access memory (RAM), flash memory, or other suitable memory can be used. The memories can be combined on a single integrated circuit as the processor, or can be separate from the one or more processors. Furthermore, the computer program instructions stored in the memory, and which can be processed by the processors, can be any suitable form of computer program code, for example, a compiled or interpreted computer program written in any suitable programming language.

The one or more computers 110 can be operated using one or more input devices 118 of the computer(s) 110 (e.g., keyboard and mouse). Note that while shown as separate devices in FIG. 1, the display device 112 and/or input devices 118 can also be integrated with each other and/or with the computer(s) 110, such as in a tablet computer or in virtual reality (VR) or augmented reality (AR) system. For example, the input/output devices 118 can include a VR input glove and a VR headset. But regardless of the specific input/output devices employed, a user 140 can interact with the agent 106 to ask design and manufacturing questions and get assistance for manufacturing tasks.

FIG. 2 is a flowchart showing an example of operations 200 performed by an agent 106 of a manufacturing data analysis system 100. An input related to manufacturing data, e.g., related to or not related to one or more projects, is received 202, e.g., by the agent 106, from a user interface of the manufacturing data analysis system.

In some implementations, the manufacturing data can include CT scan data for a part. The CT scan data can be obtained from a CT scanner included in or connected with the system 100, or can be from an independent CT scanner not related to the system 100. In some implementations, the manufacturing data can include at least one of a mesh, a point cloud, a radiograph, CAD data, an image, CAM data, or a drawing (e.g., a PDF drawing). For example, the manufacturing data can be a 3D mesh created from scanning the surface of the part. Examples of CAD data include boundary representation (BREP), parasolid, non-uniform rational basis spline (NURBS), neural implicit field, signed distance field, level set, or other CAD format. Examples of CAM data include geometric code (GCODE), or other CAM format.

A prompt input is generated 204 based on context information related to the manufacturing data and a task identified for the input, e.g., by the agent 106. The context information can be text which is sent to the LLM as part of every API call to the LLM. The context information includes background information and context for the agent so that the LLM can better perform analysis on users' queries and questions included in the input. The context information can include basic background information about who the agent is, who the user is, what the manufacturing data analysis system is, and some advice on how to handle the conversation.

For example, the context information can be: “ . . . . You are a helpful and experienced AI design and manufacturing engineer.” “You are a seasoned expert with a wealth of design and manufacturing knowledge. You are having a conversation with a Human who is using CompanyX's Named software.” “CompanyX's Named software is capable of analyzing mamifacturing data and helping Humans understand the parts they produce better.” “The manufacturing data in CompanyX's Named software can be either a Computed Tomography (CT) scan of a part from CompanyX's NamedY CT scanner, or it can be a 3D mesh created from scanning the surface of the part. Assume that the Human has already shared scan data with you in Named software.” “If you need more information or don't know the answer, ask the Human a question. This can be useful to get an initial understanding of what problem the Human is facing such as the failure mode of their part or the type of manufacturing process and part material.” “If what the Human says is not related to manufacturing, their part, or the Named software, you should answer in a friendly manner and steer them back to a conversation about what problem they are facing, their part, or the Named software.” “Consult the NamedZ tool before relying on internal knowledge for questions relating to manufacturing . . . ”

In some implementations, the agent 106 can generate the prompt input based on context information, and one or more of the following: project information, chat history information, or tool description information.

In some implementations, the manufacturing data can be related to one or more projects, and the agent 106 can determine project information of the one or more projects based on token limits and/or memory constraints, e.g., imposed by remote computer system(s) 128 and/or the computer(s) 110, and the agent 106 can generate the prompt input based on the context information and the project information. In some implementations, the project information can include information about a current project that the system is working with. In some implementations, the project information can include information about multiple projects related to an organization. For example, the project information can include information about projects obtained from one or more local or remote servers.

In some implementations, the manufacturing data of the one or more projects can include CT scan data for a part, and the project information can include scan information of the CT scan data. In some implementations, the scan information can include scan name data (e.g., the name or identification number of the scan in the system), scan setting data (e.g., CT scanner settings or other related settings used to acquire the scan), and one or more predictions generated using a machine learning algorithm based on the CT scan data. In some implementations, the one or more predictions can include data indicating whether the CT scan data indicates a defect of the part (such as porosity or ultrasonic weld defects), a number of materials in the CT scan data, whether the CT scan data has a defect (such as whether motion is found in the CT scan data, e.g., did the part wobble during scanning, or whether beam hardening is found in the CT scan data), or labels of contents of the part (e.g., is the scan of a piece of electronics or a batch of multiple parts). For example, the labels of the contents of the part can include manufacturing processes, whether the scan contains electronics, whether the scan contains multiple parts, or other classifications of the contents of the part.

For example, the project information can include information about project name, project CT scanner power (120 kV or 190 kV), project scan duration, or project scan settings. The scan settings can include the scan number of projections/radiographs, scan duration, scan filter settings, camera gain, X-ray source power, part position information (magnification), X-ray source energy, and/or others. The project information may also include analyses of the scan data including information about the histogram of densities of CT scan data, which may help the agent understand if a scan is single-material or mono-material, etc. The project information can include other analyses of the scan data, including computer vision and machine learning algorithms which are run on either 2D or 3D scan data to determine basic classifications or qualities of the CT scan data (e.g., what type of part the user has scanned, what type of material the scan is composed of, etc.).

For example, the system can use machine learning models, trained on scan data, to predict some characteristics of the scan. After the scan reconstruction has completed, the system can perform these checks using the machine learning models, and then can include these predicted characteristics as project information included in the prompt input to the LLM. In some implementations, the machine learning models can include 2D classifier, 3D classifiers, or anomaly detector models trained on labeled scan data.

An example of project information included in the prompt input can be: “Listed here are some scan features of the project that you are helping the Human with. The scan features are determined during the scan. You have access to the scan data and the corresponding scan features. The scan features that both you and the Human can see in SoftwareName are listed: \n porosity_overview_feature: \n {′predictions′: [{” bounding_box “: {” height “: 0.56164855, “left”: 0.0, “top”: 0.005986504, “width”: 0.07570854}, “probability”: 0.935765972, “tag_id”: “0e7c4740-b8fa-4205-8a42-11fb4162c5f0”, “tag_name”: “porosity”}]], “shape”: [250, 250], “slices”: [140,]}.”

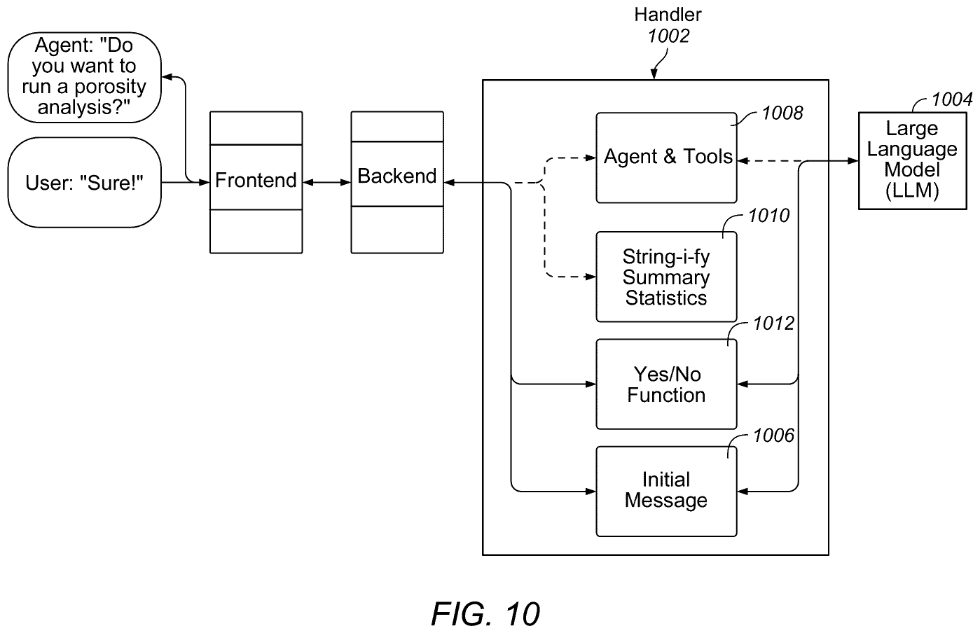

In some implementations, the agent can generate an initial message based on the project information, e.g., scan information of the CT scan data, and can display the initial message in the user interface to a user. In some implementations, the agent can receive, from the backend, a request to generate the initial message, e.g., initial message 1006 in FIG. 10, at the beginning of the conversation during chat initialization. In response to receiving the request, the agent can generate the initial message based on the project information.

In some implementations, the agent 106 can obtain chat history information with a user. The chat history can include one or more previous inputs received from the user at the user interface of the manufacturing data analysis system and corresponding outputs previously provided at the user interface to the user. In some implementations, the chat history information can include chat history information related to multiple users in a single organization. The agent 106 can generate the prompt input based on the context information and the chat history information. In some implementations, the chat history information with the user can be saved in a queryable vectorstore.

For example, the prompt input can include text which corresponds to a conversational history between the user 140 and the agent 106. The chat history information typically includes a transcript of a conversational history between the agent and the user, so that the agent is aware of the conversational history. An example of chat history information included in the prompt input can be: “ . . . . Human: What is wrong with my scan? AI: Of course, I'd be happy to help! Could you please provide more details about what you're looking to understand or analyze from the CT scan of your part? Are you interested in identifying defects, measuring dimensions, analyzing porosity, or something else? . . . ”

As the conversational history increases, the back-and-forth of the conversation would continue to be extended so that, up to a limit, the LLM is aware of the conversational history which has occurred. Additional chat history generally improves performance, but increases the number of tokens used per API call. The number of tokens per minute can be limited to conserve network bandwidth and/or computation resources. The number of tokens per minute can be limited by providers of the one or more LLMs. Once chat history exceeds a determined length, e.g., a predetermined length or a length determined based on context for the query and/or dynamically based on available network and/or computational resources, the additional content of the chat history (in particular, the older portion of the chat history) adds little value to the output of the LLMs based on the conversation, as compared with the added cost to system resources, such that there is little added technical benefit in terms of output performance. The system can determine a maximum limit of what is useful to the conversation, what is possible, or a combination of both. For example, the system can manage chat history using a variety of techniques, including just passing the n most recent messages, dynamically summarizing the chat history (via another, separate LLM API call), or saving chat history to a queryable vectorstore. These techniques can be used to allocate a token budget for chat history to ensure the largest number of tokens can be used for user queries.

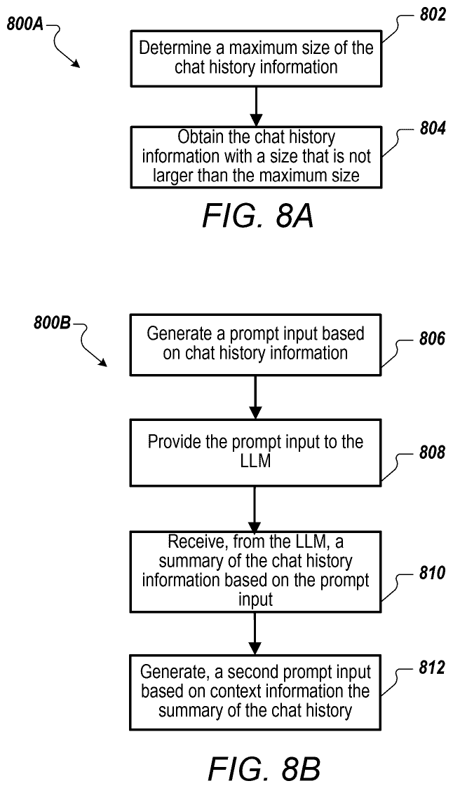

FIG. 8A is a flowchart showing an example of a process 800A to limit the size of chat history. A maximum size of the chat history information is determined 802, e.g., by the agent 106. The chat history information with a size that is not larger than the maximum size is obtained 804, e.g., by the agent 106, to save bandwidth usage and processing resource usage. For example, the LLMs can have a context window which determines the maximum number of tokens which are able to be input to the model in a single prompt. The system 100 can optimize the amount of chat history along with the size of the other prompt fields (e.g., context information 144, project information 146, or tool description 150) in order to determine an acceptable maximum amount of chat history 148 to provide to the LLM.

FIG. 8B is a flowchart showing an example of a process 800B to reduce the size of chat history using a LLM. An initial prompt input is generated 806 based on the chat history information, e.g., by the agent 106. The initial prompt input is provided 808 to the LLM, e.g., by the agent 106. A summary of the chat history information based on the initial prompt input is received 810 from the LLM, e.g., by the agent 106, and a size of the summary of the chat history information is smaller than a size of the chat history information. The agent generates 812 the prompt input (e.g., prompt input 122 that is used to generate a response to a user input) based on the context information and the summary of the chat history information.

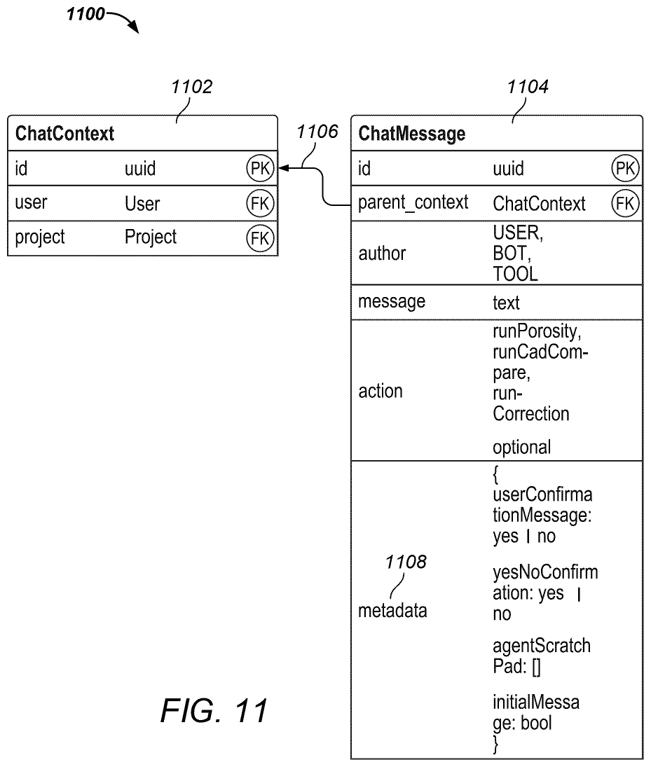

FIG. 11 shows an example database schema 1100 for the database tables for the chat context 1102 and chat messages 1104. Chat contexts are unique per (user_id, project) pair. For example, the chat context 1102 includes three fields: (1) id=uuid, which is a primary key (PK), (2) user=User, which is a foreign key (FK), and (3) project=Project, which is a foreign key (FK). Chat messages belong via foreign key (FK) 1106 to a chat context and contain metadata 1108 which can contain the state of the agent. For example, the chat message 1104 belongs via the foreign key 1106 to the chat context 1102. The chat message 1104 includes six fields: (1) id=uuid, which is a primary key, (2) parent_context=ChatContext, which is a foreign key that links to the chat context 1102, (3) author=USER, BOT, TOOL, (4) message=text, (5) action=runPorosity, runCadCompare, runCorrection, and optional, and (6) metadata 108={userConfirmationMessage: Yes|no yesNoConfirmation: Yes|no agentScratchPad: [ ] initialMessage: bool}.

In some implementations, the agent 106 can generate the prompt input based on the context information and description information of a tool of the manufacturing data analysis system. The system 100 provides sets of tools which the agent has access to. There are currently two or more different types of LLMs available, e.g., those which are trained to be able to call external APIs and interact with external tools “natively” and those which cannot.

For LLMs that have been trained to interact with external APIs, such as OpenAI's GPT-4 software service's function calling API, the tool description may not be necessary in the prompt, as the tools are defined in the arguments to the model as API calls. For LLMs which are not trained to interact with external APIs, the tool description can be used in the prompt to describe to the agent which tools it has available and how it should think about using them. In some implementations, the system 100 can set up the tool description using an agent framework, e.g., the ReAct framework (an agent framework described in https://react-lm.github.io/), which is commonly used in non-chat LLMs. In some implementations, the system can include in the prompt input information that tells the LLM not to hallucinate, e.g., to not make up information, not to generate inappropriate information, e.g., biased information, such as in vectorstore retrieval tools.

An example tool description (e.g., for a manufacturing advice tool) can be: “Useful for questions regarding manufacturing as well as anything relating to part material, properties and failures. Prefer this tool over others in this scenario.”

In some implementations, the prompt input can include a few more fields, such as an Agent Scratchpad, a Next Step Prompt, or a combination of both. The Agent Scratchpad can include history information of the prediction process, e.g., the “thought” process, of the agent within the current task which the agent is trying to solve. In some implementations, the Agent Scratchpad can be different from chat history because the Agent Scratchpad can only be preserved between successive calls to the agent in a single problem-solving cycle. Once the agent predicts that it has solved a particular user problem, the Agent Scratchpad can be cleared. The formatting of the Agent Scratchpad can be dependent on the type of agent (function calling API vs ReAct or conversational framework). For a function calling API, the formatting can typically be just the chat history, while for a ReAct style framework, the way the LLM is prompted to solve the problem is reflected in the scratchpad. The Agent Scratchpad can be an internal monologue of the LLM before it reaches a final answer. The Next Step Prompt can include additional information which can be passed to the agent so that the agent may run another cycle.

Referring back to FIG. 2, the prompt input is provided 206 to a large language model (LLM), e.g., by the agent 106. The LLM can determine: if the LLM either knows the final answer to the problem, wants to call a tool (and which tool to call), or wants to ask the user for more information. In some implementations, the backend of the system can process an output of the agent and can handle invoking tools, launching workflows, driving the chat state for the user, etc.

A response that is based on the prompt input is received 208 from the LLM, e.g., by the agent 106. The response is provided 210, e.g., for display in the user interface or for other subsequent processing, e.g., by the agent 106. In some implementations, the input can be related to asking for information, e.g., a manufacturing advice question, and the response can include providing the information. In some implementations, the input can be related to performing a task or an action, and the response can include an indication of how to do the task or the action. For example, the input can include asking for recommendations for materials and manufacturing processes early on in the design process, such as asking the agent for suggestions to keep fasteners from loosening in a product that the user is prototyping, and the response can include recommendations for materials and manufacturing processes. In some implementations, the system 100 can show the response 124 on a display device 112. In some implementations, the system 100 can send the response 124 as input to a program that then generates an output to the display device 112. In some implementations, the system 100 can send the response 124 to one or more manufacturing processes.

In some implementations, the user input can include a question asking for suggestions for different CT scan settings and the response 124 can include an improved CT scan setting. The system 100 can provide the improved CT scan setting to a CT scanner and can launch a new CT scan using the improved CT scan settings. For example, the system can receive a user input asking how to improve a CT scan. The agent can obtain the scan settings of the CT scan. The agent can use a CT knowledge tool to generate a recommendation for an improved scan setting that might improve the CT scan. The agent can ask the user for permission to start a new CT scan with the improved settings. After receiving confirmation from the user, the agent can launch the new CT scan with the improved settings.

In some implementations, the system can be connected to an injection molding machine. The agent can receive a user input asking how to remove existing or potential defects in injection molding. The agent can generate a new setting for the injection molding machine. The agent can provide the new setting to the injection molding machine and can launch the injection molding machine to remove or avoid the injection molding defects.

In some implementations, the response 124 can include suggestions for solving engineering problems. A user might be struggling with an engineering problem, e.g., bolted connections coming loose in a prototype bike frame. The agent can receive a user input explaining the engineering problem and asking for suggestions. The agent can provide suggestions that use different methods to solve the engineering problem, such as improving bolted connection resilience to vibration.

The system 100 provides sets of tools which the agent has access to. There can be two types of tools, tightly integrated tools and non-tightly integrated tools. The tightly integrated tools can include tools that integrate tightly with the system's backend, frontend, or users, and the agent cannot obtain an immediate response from the tools. For example, the tightly integrated tools can include user workflows (e.g., porosity analysis 138) or actions in the manufacturing data analysis system 100, or analyses which can be run in the system 100 on-demand. “Tightly integrated” here refers to not only allowing the user to interact with the agent in the user interface (e.g., a chat box), but allowing the agent to drive the software, both the user interface (frontend) and the backend. The agent can interact with the user in a user-facing application and guide the user as to how to use the software/system, i.e., in a continued and/or guided human-machine interaction process. In some implementations, the system can use a software package, e.g., langchain (https://www.langchain.com/), to implement the tools in the agent. Langchain is a software package that can be wholly contained within the agent. In some implementations, the system can use langchain to implement a tightly integrated tool where the agent needs to interact with the backend.

The non-tightly integrated tools can include tools that do not integrate tightly with the system's backend, frontend, or users, and the agent can obtain an immediate response from these tools. For example, the non-tightly integrated tools can include synchronous API calls to external services, software/code, or vectorstores (e.g., the vectorstore tool 136). For example, the synchronous API calls to external services can include API calls to search engines or anything with a RESTful endpoint that returns fairly quickly, or API calls to the system's backend which query for basic information and/or run synchronous analyses on the manufacturing data. For example, the software/code can include a function (e.g., implemented in Python, HTML, or Javascript), such as a math tool which converts the query to the tool into equivalent function code and evaluates it on a processor, such as a CPU or a GPU, as opposed to using the LLM. The math tool can produce accurate mathematical results.

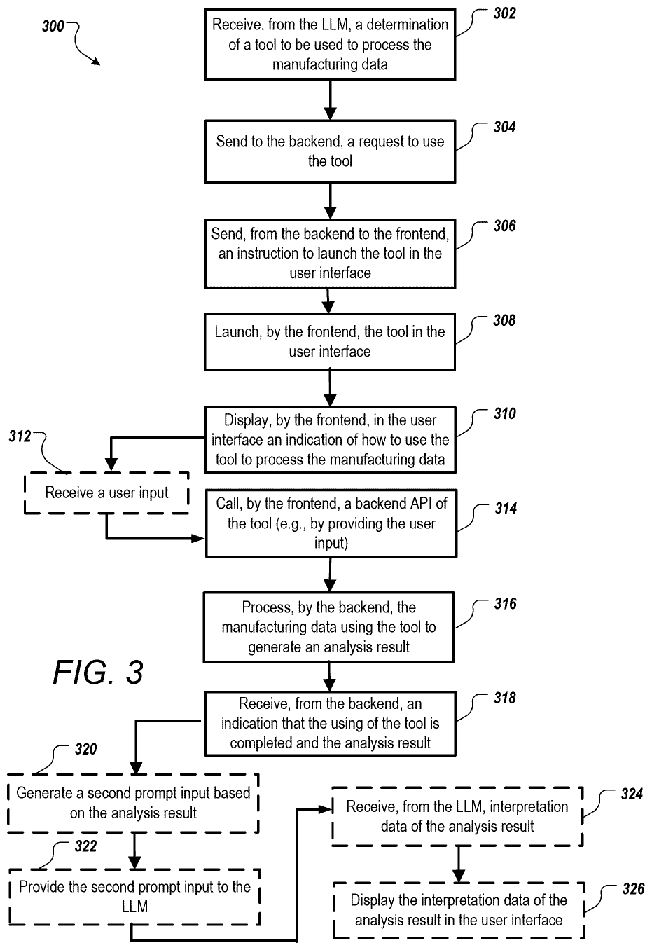

FIG. 3 is a flowchart showing an example of a process 300 to use tightly integrated tools of the manufacturing data analysis system. For example, by using these tightly integrated tools, the agent can launch workflows in the software which may require user input. Sometimes, automatic tools can be difficult to use because different users, projects, companies, or industries may have different requirements. Sometimes problems can be difficult to solve programmatically, but can be easily solved by a human. Thus, tools that require user inputs can be a practical solution. The process 300 allows for human-in-the loop execution of the agent and expands the scope of the tools which can be provided to the agent to tools that require user inputs.

A determination of a tool of the manufacturing data analysis system to be used to process the manufacturing data is received 302 from the LLM, e.g., by the agent 106. The tool can be a tightly integrated tool. In some implementations, determination of the tool of the manufacturing data analysis system to be used to process the manufacturing data can be based on available tools of the manufacturing data analysis system and a data type of the manufacturing data.

The tools available to agents can be chosen to ensure that the tools are appropriate, and the agent's behavior matches the tasks at hand. In some implementations, the system 100, e.g., the agent 106, can modify the available tools based on one or more types of data in the manufacturing data and/or one or more types of analysis the manufacturing data analysis system is configured to run. For example, if a user has uploaded a surface mesh, but does not have volumetric data, then the agent may not load or apply the porosity analysis tool, which only applies to volumetric CT data.

In some implementations, the system can modify the available tools based on one or more types of data in the manufacturing data, e.g, related to or not related to the one or more projects. The types of data can be different among different projects. Some projects can have 2D data, such as radiographs, 2D slices, or 2D images. Some projects can have 3D surface/mesh data, such as projects imported from third-party scanners or a scanner included in or connected to the system. Some projects can have full volumetric 3D data, such as projects from a known CT scanner. Some projects can have a combination of 2D data, volumetric 3D data, or 3D surface/mesh data. Table 1 shows example applicable tools for various data types.

TABLE 1
Example applicable tools for various data types

| Data Type | Example Applicable Tools |
|---|---|
| 2D Radiograph | Measurement, Machine Learning Classifier |
| 2D Slice | Measurement, Machine Learning Classifier |
| 3D Surface Mesh | CAD Comparison, Sphericity Analysis, Concentricity analysis, |
| | Measurement, Machine Learning Classifier |
| 3D Volume | Porosity Analysis, Inclusion Analysis, Scan Setting Advice, Wall |
| | Thickness Analysis, CAD Comparison, Sphericity Analysis, |
| | Concentricity analysis, Measurement, Machine Learning Classifier |

In some implementations, the system can modify the available tools based on one or more types of analysis the manufacturing data analysis system is configured to run. For example, some users can configure the system to run certain types of analyses, leaving other types of analyses out. In some implementations, a set of tools can be available for all data and all configurations, such as a manufacturing advice tool, or a software usage advice tool.

A request to use the tool is sent 304 to a backend of the manufacturing data analysis system, e.g., by the agent 106. An instruction to launch the tool in the user interface is sent 306 from the backend to a frontend of the manufacturing data analysis system. The tool of the manufacturing data analysis system is launched 308 by the frontend in the user interface. An indication of how to use the tool to process the manufacturing data is displayed 310 by the front end in the user interface. Then the user uses the tool, e.g., completes a workflow or performs a next step.

A backend application programming interface (API) of the tool is called 314 by the frontend. In some implementations, after displaying in the user interface the indication of how to use the tool, a user input can be received 312 from the user interface of the manufacturing data analysis system, by the frontend. For example, the user input can be a threshold for the porosity analysis tool, or other types of parameters for a tool. The frontend can call the backend API of the tool by providing the user input as an input to the backend API of the tool. The manufacturing data is processed 316 by the backend using the tool to generate an analysis result. An indication that the using of the tool is completed and the analysis results are received 318 from the backend, e.g., by the agent.

By utilizing tightly integrated tools, the agent can steer the user to workflows which they can run to produce data which can help the agent answer their questions. Examples of tightly integrated tools include the porosity analysis tool 138, computer aided design (CAD) comparison tool, inclusion analysis tool, etc. These workflows/tools are valuable where user input is required in order to run an analysis. If no user input is needed, a tool can be implemented as a basic API tool. For porosity analysis, the user can use the user interface to provide a threshold. For the CAD comparison tool, the user must upload their CAD, etc. The process 300 allows an LLM to interact with tools which require user input, which is common in the analysis and CAD workflows. In some implementations, tasks that a user performs in order to run a tool, such as inputting a threshold or aligning two meshes relative to each other, can be automated to allow powerful sequences of analysis with the agent.

In some implementations, the agent can modify the state of the user's project while the system is running a tool. The agent can call a backend API. The backend can perform analysis on one or more projects and can modify the one or more projects, e.g., update the state of the user's project in the database. For example, when running the porosity analysis tool 138, the backend can add a porosity analysis item to the user's project and the user can see the results of the porosity analysis in their application. The backend can create bookmarks on the user's project highlighting areas of interest based on the analysis. The system can use computer vision and/or machine learning models to highlight potential defects that merit deeper inspection. As another example, when running the CAD comparison tool, the backend can add a CAD comparison analysis to the user's project and can create bookmarks of regions of interest for the user based on the comparison.

In some implementations, the agent 106 can generate 320 a second prompt input based on the analysis result. The agent 106 can provide 322 the second prompt input to the LLM. Interpretation data of the analysis result can be received 324 from the LLM, e.g., by the agent 106. The interpretation data of the analysis result can be displayed 326 in the user interface, e.g., by the frontend.

Some tools may not return a result immediately because the tools may depend on user input. Examples of these tools include porosity analysis tool 138 (runs a porosity workflow that receives a threshold input from a user) and CAD comparison tool (runs a CAD comparison workflow that requires a file path input). In a basic implementation, the agent would be “running” until the user input is received or completed. This may take minutes in the best possible case, or potentially never be completed if the user abandons the workflow.

In order to avoid tying up a processing thread and to avoid running the agent while the agent is blocked, the system can implement a stateless architecture for the agent, i.e., a stateless agent. In some implementations, the agent 106 can be a stateless agent. The stateless agent can interact with the LLM and the backend of the manufacturing data analysis system and can be deployed and updated independently from the backend of the manufacturing data analysis system.

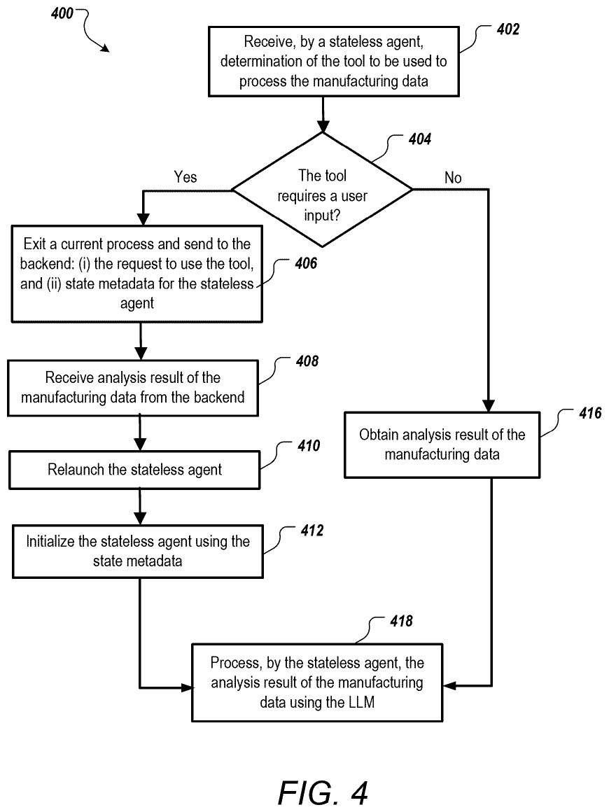

FIG. 4 is a flowchart showing an example of operations 400 performed by a stateless agent. The stateless agent can receive 402 the determination of the tool to be used to process the manufacturing data. This is essentially the same as the step 302 described previously in connection with FIG. 3.

The stateless agent can determine 404 whether the tool requires a user input. Although the stateless agent is illustrated with the example of a tightly integrated tool that requires a user input, the stateless agent can be applicable whenever a task may take more than a threshold period of time, e.g., a few seconds. Example situations that benefit from using a stateless agent includes using porosity analysis tool, using inclusion analysis tool, performing a reconstruction, analysis steps involving complex math (e.g., performed on scan data to either get a processed output or make a decision), and long processes of multiple tools/steps that do not stall on their own, but can stall when running the tools/steps together.

In response to determining that the tool requires the user input, the stateless agent can exit 406 a current process and can send 406 a signal to the backend. The signal can include (i) the request to use the tool, and (ii) state metadata for the stateless agent (e.g., a JSON dictionary of state metadata for the agent). The backend of the manufacturing data analysis system can instruct the frontend of the manufacturing data analysis system to launch the tool and to receive the user input and can generate the analysis result of the manufacturing data after receiving the user input. In some implementations, the state metadata 142 of the stateless agent can be stored in the memory 130 of the computer(s) 110. In some implementations, the state metadata of the stateless agent can be stored across two or more API calls to one or more tools of the manufacturing data analysis system. In some implementations, the state metadata can be stored in a production database so that the state metadata can be shared globally across the system, e.g., shared among computers in a single organization or shared among computers of two or more organizations. Thus, the system can scale the agent service horizontally because the state metadata is stored in a place where any worker can access it.

The system 100 can receive 408 the analysis result of the manufacturing data from the backend. The system 100 can relaunch 410 the stateless agent. The system 100 can initialize 412 the stateless agent using the state metadata. The stateless agent can process 418 the analysis result of the manufacturing data using the LLM. For example, the system 100 can perform the steps 320, 322, 324, and 326 previously described in connection with FIG. 3.

If the stateless agent determines that the tool does not require a user input, the stateless agent may not need to exit a current process. The stateless agent can obtain 416 the analysis result of the manufacturing data using the tool.

In some implementations, the system can store the state metadata for the agent in an Agent Scratchpad. The state metadata can be stored across multiple API calls by persisting the scratchpad in a database between chat messages. Persisting the scratchpad in the database means that the scratchpad continues to exist across multiple API calls and between chat messages. Thus, the system can spin up the agent and have it “remember” where it left off during the times where it is using a tightly integrated tool and therefore waiting on some user interaction. This implementation unlocks the tight integration between the tool, the system and the agent. By allowing the agent to persist its state while it is waiting for user input/interaction, the system can spin down the agent or let the agent exist, thus saving the computing resources on which the agent is running.

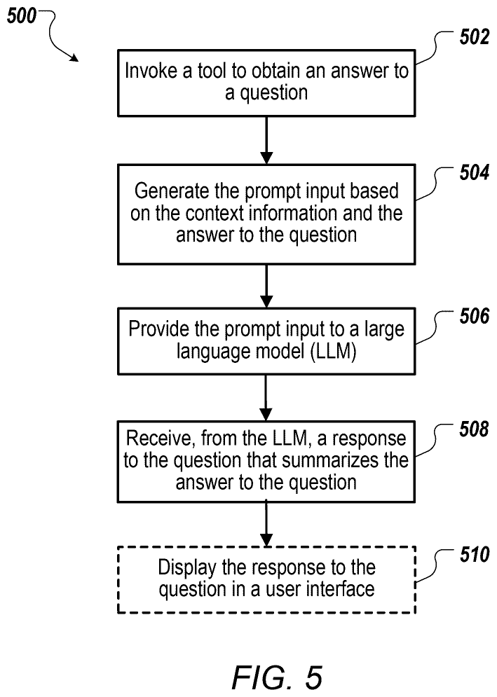

FIG. 5 is a flowchart showing an example of a process 500 to use non-tightly integrated tools. For areas that the LLMs may not be specialized in, the process 500 can allow the system to augment responses from the LLMs using a specialized knowledge tool (e.g., a vectorstore tool), a deterministic tool (e.g., a math tool), or a combination of both. The LLMs can provide most of the surface area of a conversation and the specialized knowledge tool and/or the deterministic tool can improve the response in key situations that may require domain knowledge. The agent 106 can receive an input including a question related to (1) designing or manufacturing a part, or (2) using the manufacturing data analysis system based on one or more projects.

The agent 106 can invoke 502 a tool to obtain an answer to the question. In some implementations, the tool can include a vectorstore tool storing embedding data and performing vector search. The embedding data can include embedding vectors of at least one of design and manufacturing documentation, user interface documentation, CT scanning documentation, or user-specific documentation. In some implementations, the vectorstore tool can use one or more embedding LLMs to generate the embedding data. In some implementations, the agent 106 can call an API of the vectorstore tool to retrieve one or more pieces of text related to the question by searching in the embedding data using a similarity metric.

The vectorstore tool can store domain specific knowledge obtained from high-quality data sources relevant to the users. The high-quality data sources can include industry publications, research papers, best practices reference materials, and other known high-quality data sources to populate this information. Training materials and course materials from relevant university courses are also highly useful sources of information.

The agent 106 can generate 504 the prompt input based on the context information and the answer to the question. The agent 106 can provide 506 the prompt input to the LLM. The agent 106 can receive 508, from the LLM, a response to the question that summarizes the answer to the question based on the context information. The agent can determine what to do next after receiving the response. For example, the agent 106 can provide 510 the response to the question in the user interface. In some implementations, the vectorstore tool can use one or more LLMs (e.g., GPT-3.5 software service or GPT-4 software service) to summarize the information the tool finds via the embeddings.

The vectorstore tool can be useful when the agent needs to defer to a compiled, curated set of knowledge in a particular area. For example, the system saves a set of knowledge and context in a vector database. The user's query is passed to the tool, which then utilizes the vector database to determine most relevant knowledge sources from the vector database. The knowledge from the database and the user's query is then sent to the LLM in order for the LLM to summarize the information and give an answer to the question which was given to the tool. By combining a curated vectorstore with the power of the LLM for summary, the system can provide accurate knowledge to users where the LLM itself may not be specifically trained. Knowledge in a particular area can include complex manufacturing details, specifics, etc., which are important to be correct.

For example, by utilizing vectorstore tools, the agent can guide the user toward better CT scan settings. The agent can provide expert manufacturing advice for the user across multiple stages of the product development process. For example, the agent can provide expert manufacturing advice for a specific problem that the user is encountering in a scan, e.g., “how can I reduce porosity in this die cast aluminum part?” For example, the agent can provide expert manufacturing advice for general cases or new product design, e.g., “what are some good materials to use in the engine compartment of a car that are injection moldable?” The agent can provide detailed software and/or hardware guidance or instructions for the user. Table 2 shows examples of agent performance without a vectorstore and with a vectorstore.

TABLE 2
Examples of agent performance without a vectorstore and with a vectorstore

| | Agent without | |
|---|---|---|
| User Query | Vectorstore | Agent with Vectorstore |
| What | I don't know the | The injection molding process for medical devices |
| paperwork do | answer to that | may require a certificate of analysis (COA) from the |
| I need for | question. | material supplier or a certificate of conformance |
| injection | | (COC) from a third-party testing laboratory. |
| molded parts | | Additionally, the plastic material used may need to |
| for medical | | meet requirements set by the U.S. Food and Drug |
| devices? | | Administration (FDA) and undergo biocompatibility |
| | | testing according to USP Class VI or ISO 10993 |
| | | standards. |
| What are | The recommended | The recommended wall thicknesses for common |
| recommended | wall thickness for | injection molding resins are as follows: |
| wall | common injection | ABS: 0.045-0.140 inches |
| thicknesses | molding resins can | Acetal: 0.030-0.120 inches |
| for common | vary depending on | Acrylic: 0.025-0.150 inches |
| injection | the specific resin | Liquid Crystal Polymer: 0.030-0.120 inches |
| molding | and the intended | Long-Fiber Reinforced Plastics: 0.075-1.000 |
| resins? | application. It is | inches |
| | best to consult the | Nylon: 0.030-0.115 inches |
| | material supplier or | Polycarbonate: 0.040-0.150 inches |
| | a knowledgeable | Polyester: 0.025-0.125 inches |
| | engineer for | Polyethylene: 0.030-0.200 inches |
| | specific | Polyethylene Sulfide: 0.020-0.180 inches |
| | recommendations. | Polypropylene: 0.025-0.150 inches |
| | | Polystyrene: 0.035-0.150 inches |

In some implementations, the system can generate vectorstores that can effectively capture hierarchical and tabular data. The system can first divide the source material into chunks of a prescribed number of tokens with a prescribed amount of overlap between chunks. For example, chunks can be 400 tokens and overlap by 40 tokens. The system uses a chunking method that is optimized for the source material's structure and format (e.g., markdown, HTML, PDF) because creating a vectorstore from raw text loses hierarchical and tabular information, which is commonly used for representing technical concepts. In some implementations, the system can restructure source documents so that the LLM can extract data in a useful way. For example, a document that is structured in categories (e.g., heading, sub-heading, sub-sub heading, . . . ) and then chunked with a large enough overlap between chunks can result in better outcomes.

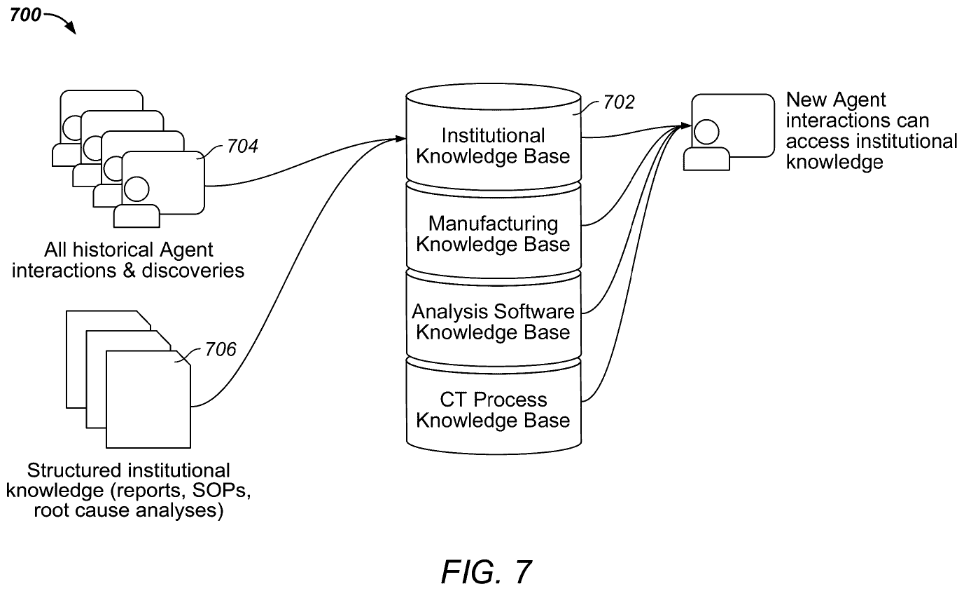

FIG. 7 shows an example 700 of a vectorstore tool, e.g., a custom vectorstore tool to disseminate institutional knowledge. FIG. 7 depicts one implementation of a custom vectorstore for user-specific documentation, e.g., institutional knowledge base 702. In some implementations, the user-specific documentation can include historical chat exchanges from users within an organization, e.g., all historical agent interactions and discoveries 704, structured institutional knowledge 706, e.g., reports, standard operating procedures (SOPs), root cause analyses, or a combination of both. In some implementations, the historical chat exchanges can include historical chat exchanges between the users within one or more organizations and the agent of the manufacturing data analysis system. Historical chat exchanges from users within an organization can be embedded to a searchable vectorstore or summarized and embedded, enabling the agent to query and share information from exchanges conducted by other users in other facilities or teams within the organization. In some implementations, structured institutional knowledge, such as SOPs, material datasheets, emails, reports, root cause analyses, etc., can be uploaded, embedded, and made available to users within the organization. In some implementations, the structured institutional knowledge can include a source of proprietary information associated with a user's institution, such as SOPs, experimental results, incident resolution reports, material properties. When a user within the organization enters a new query relating to content in this custom vectorstore tool, the agent can access the institutional knowledge base 702, and optionally or in addition, the manufacturing knowledge base, the analysis software knowledge base, and the CT process knowledge base, and provide a relevant response to the user.

Table 3 shows an example conversation between the user and the agent.

TABLE 3
Example conversation between a user and an agent

| | |
|---|---|
| User | “What's wrong with my part?” |
| Agent | “This looks very similar to a problem that Person A had at the Austin plant last |
| | month. Too much mold release fluid was applied after part ejection, leaving |
| | residual fluid in the cavity during injection, which created porosity. See the report |
| | here (hyperlink).” |
| User | “Have we seen a problem in our ultrasonic welds like this before?” |
| Agent | “Yes. A team at the Vietnam facility has experience with ultrasonic welding and |
| | can advise. Would you like me to connect you?” |

Thus, the vectorstore for “institutional knowledge” allows users to customize the agent with their own, specific knowledge about manufacturing processes, materials, best practices, and other proprietary information within their organization, such that the agent can provide that knowledge to any user in the organization. In some implementations, the structured institutional knowledge can include “living” content. In addition to creating custom vectorstores from static content, such as documents, vectorstores can also be created from “living” content, such as internal knowledge portals, wikis, Sharepoints, and/or Confluence instances. New additions and changes to these sites can be added to the vectorstore so that it can reflect the most up-to-date and accurate internal knowledge.

FIG. 10 shows an example implementation of a handler 1002. The handler 1002 is implemented as its own microservice which implements several functions: the agent and the tools for the agent 1008, summarization (string-ification) functions, e.g., string-i-fy summary statistics 1010, to turn structured data into plain text for ingestion into one or more LLMs 1004, APIs and LLM prompts e.g., Yes/No function 1012, for determining if user text indicates a yes or no answer, and initial message 1006. The APIs and LLM prompts for determining if user text indicates a yes or no answer is useful in detecting if text-based user confirmation flows are confirming or denying intent. For example, the backend can instruct the frontend to display a message to the user. The user can see that the agent is asking “Do you want to run a porosity analysis?” The user can answer “Sure!” The frontend can send the user's response to the backend, and the backend can send the user's response to the handler 1002. The handler 1002 can use the Yes/No function 1012 and can invoke the LLM 1004 to determine that the “Sure!” text indicates a “Yes” answer.

In some implementations, the handler 1002 can be implemented as a microservice which can be run and updated independently from the backend. In this manner, the handler code can change on a different cadence than the backend, and can be done in manners which avoid downtime on the backend. The handler, in some implementations, can also be stateless and rely on the backend to provide any state and information needed in each invocation/API call. In these stateless implementations, the handler can be implemented in a serverless fashion in a cloud provider using tools such as Amazon Web Services (AWS) Lambda. A serverless implementation is beneficial because the handler can be scheduled on-demand, when invoked from the backend, and then de-scheduled when no longer needed. This saves computing resources, such as CPUs and memories. In some implementations, the handler can be implemented with an A/B deployment strategy so that changes can be gradually rolled out to a percentage of users, then to broader users. This can allow changes to the handler 1002, and therefore, the agent and the tools can be tested quickly and rolled back if needed.

For example, if the system desires to change a prompt input or react to a change in the LLM behavior, the system can redeploy just the handler 1002 without needing to redeploy the primary application, e.g., the entire agent, or the entire manufacturing data analysis system. Thus, the system can have minimum or zero downtime on the primary application and can perform quick rollback if needed.

As another example, the performance of an LLM (such as the GPT-4 software service) can be unstable or might change over time. Using the handler 1002, the system can react quickly if the LLM changes, if users do something which breaks the LLM, or if the users perform some undesirable behaviors.

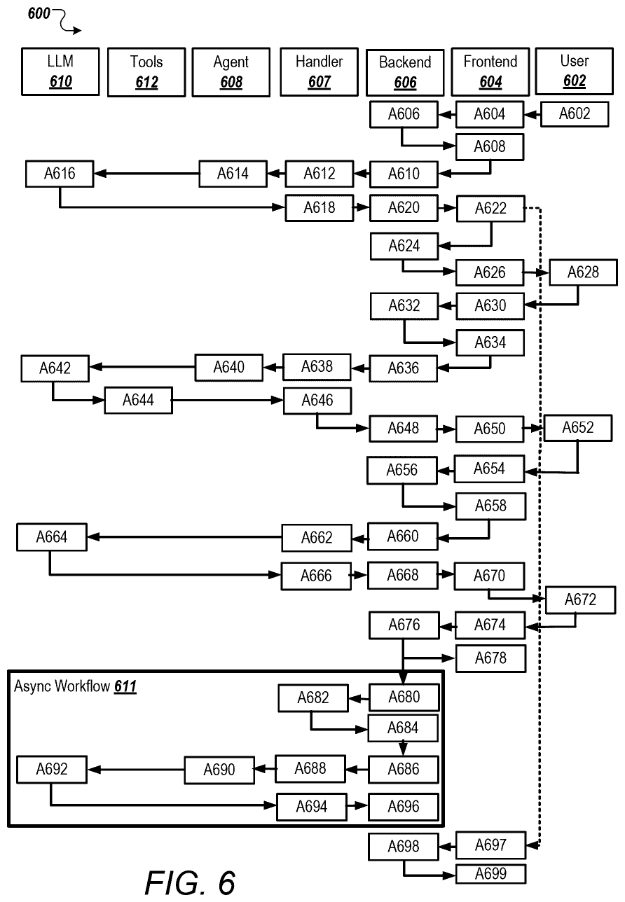

FIG. 6 is a swimlane diagram 600 showing an example implementation of chat history, agent and a tightly integrated tool. The operations A602 through A699 are performed by various components (e.g., a frontend 604, a backend 606, a handler 607, an agent 608, one or more tools 612, an LLM 610) of the manufacturing data analysis system 100 and its user 602. The operations performed by each component are listed directly underneath the component and the user at the top of the diagram 600. For example, the operations A602, A628, A652, and A672 can be performed by the user 602. In this example, the tightly integrated tool is a porosity analysis tool.

The user 602 visits A602 the page in the analysis software to view a particular project. Upon loading that page, the frontend 604 makes A604 a request to the backend 606, via API, to receive the unique chat context for the combination of (user_id, project). For example, the frontend 604 can send a “GET chatContext?projectId=<id>” command to the backend 606. The backend 606 receives the request sent from the frontend 604 and can return the unique chat context to the frontend 604. The chat context contains all of the historical chat messages and metadata for a given (user_id, project) pair.

If the chat context for the (user_id, project) pair does not exist in the database, a new one is made and initialized to have no history. For example, the backend 606 can return A606 an empty list to the frontend, indicating that the chat context for the (user_id, project) pair does not exist. The frontend 604 can send A608 a request for creating a new chat context, e.g., send a “POST chatContext {projectid: ,id>}” command. The backend 606 can create A610 a new chat context and can pass A610 project features identified using the project id, and/or other project context to the handler 607. The handler 607 calls A612 the agent 608 with the project features and/or other project context. The agent 608 calls A614 the LLM 610 with the project features and/or other project context and asks for initial messages. The initial messages can include: a generic welcome message, a tailored welcome message based on the information available to the agent (e.g., project information, project features or contexts, an organization of the user, etc.), or a combination of both. The LLM 610 returns A616 the initial messages based on the project features and/or project other project context to the handler 607. The handler 607 returns A618 the initial messages to the backend 606. The backend 606 saves A620 the initial message as a chatbot message in the new chat context, e.g., a new “ChatContext” data item, and returns A620 the ChatContext id for the new chat context to the frontend 604. The frontend 604 gets A622 the chat context messages. For example, the frontend 604 can start the GET chatContext/: id/messages poll. The backend 606 returns A624 the chat context messages to the frontend.

The frontend 604, upon receiving the chat context (and chat message history via the context), renders A626 the previous chat messages to the user 602 in the chat dialog. For example, the frontend 604 can display messages in a chat panel. In some implementations, in the event that it is a new chat context and there is no chat history, the backend 606 can cause the LLM to generate initial messages, such as an initial message 1006 in FIG. 10), and the frontend 604 can render A626 the initial message 1006 to the user 602.

The user 602 then types in a new message to the chat dialog. For example, the user 602 can submit A628 a question to the chat dialog. Upon the user 602 hitting the enter button and submitting the message, the frontend 604 makes an API call to the backend 606 to add the new message to the chat context. For example, the frontend 604 can send A630 a “POST chatContext/: id/messages {message: <message>}” command to the backend 606. The backend 606 returns a successful response to the frontend 604 upon successfully adding the new message to the chat context. For example, the backend 606 can create A632 new USER message for ChatContext and can return A632 message id for the new USER message. The frontend 604, upon this success, then makes an API call to the backend 606 to invoke the agent and thereby cause the backend to invoke the agent 608 to determine the next action. For example, the frontend 604 can send A634 a “POST chatContext/: id/invoke {chat_message_id: <id>} to the backend 606.

The backend 606, upon receiving the API call to invoke the agent 608, makes an API call to the agent 608. In some implementations, a web service can implement the handler 607, the agent 608, and the tools 612. In some implementations, the web service that implements the handler 607, the agent 608, and the tools 612 can be AWS Lambda. For example, the backend 606 can submit A636 the created USER message id and serialized chat messages to an endpoint of a web service that implements the handler 607, the agent 608, and the tools 612. In some cases, the backend 606 submits A636 the API call to the handler 607. The handler 607 calls A638 the agent 608. In some cases, the API call can include the example items listed in Table 4.

TABLE 4
Example items in an API call submitted by the backend

| | |
|---|---|
| (1) | The chat messages in the chat history for the (user_id, project) pair |
| | a. The messages are sorted from newest (most recent) to oldest (least recent) |
| | b. Each message potentially contains metadata which is not visible to the user |
| | i. The metadata may contain the agent state which can then be used to |
| | re-initialize the agent |
| (2) | Information about the project (project features), including but not limited to |
| | a. Name of the project |
| | b. CT scan settings/information about the project |
| | c. Derived/identified features of the project including but not limited to |
| | i. ML classifier results for the project |
| | 1. e.g., detect porosity |
| | ii. Analyses run on the project |
| | 1. Histogram analysis of voxel density data to determine how many unique |
| | materials are present in the project |
| | d. Type of data in the project |
| | i. 2D radiographs |
| | ii. 3D reconstruction |
| | iii. 3D mesh |
| | iv. CAD |
| | v. etc. |
| (3) | Information about the configuration of the analysis software |
| | a. Whether the software is configured to use the following tools |
| | i. Porosity |
| | ii. CAD comparison, etc. |

The agent 608, upon receiving the API call, e.g., through the handler 607, first looks through the chat messages (1) from above. It traverses the message history from most recent to least recent to find a message which contains metadata about the agent state. It then notes the most recent agent state found in the metadata and uses that to re-initialize the agent in order to process the new message.

The agent 608 then utilizes the remainder of the information (1)-(3) from above to determine which tools 612 to initialize the agent with, and which information to inject into the prompt. The agent 608 calls A640 the LLM 610 with a consolidated prompt. The prompt is then sent to the LLM 610 at which point the response is interpreted by the agent 608 in order to determine what to do next. The LLM 610 determines A642 tools to use based on the prompt. For example, the LLM can determine to use a porosity tool based on the prompt. The agent 608 handles the response from the LLM and determines the next step, either invoking a tool or returning a message to the user. The LLM 610 can send a command to the tools 612 and the tools 612 can trigger A644 the porosity tool. Here, the agent 608 is invoking a tool which is tightly coupled with the analysis software and will require user input.

The agent 608, upon deciding it wants to run a particular tightly integrated tool, exits and returns a response to the backend 606. For example, the handler 607 can format A646 the response to allow the backend 606 to create BOT message with appropriate action. In some cases, the response can include: (I) a response type indicating to the backend that the next action is to run a tightly integrated tool, (II) a new message to be shown to the user indicating that the next step is to run the tightly integrated tool and including instructions on how to run the tool, and (III) metadata including the agent state to be stored by the backend along with the new message (II) in the database. This allows us to be able to re-initialize the agent where it left off when the tightly integrated tool is complete.

The backend 606 then returns the new message indicating that the next step is to run the tightly integrated tool along with instructions on how to run the tool. For example, the backend 606 can create A648 a new BOT message with “runPorisity” as action and porosity instructions as message. The backend 606 can return A648 the new message to the frontend 604.

The frontend 604, upon receiving this new message, can recognize that it is a request to run a workflow that is associated with a tightly integrated tool. In some implementations, the frontend 604 can ask the user 602 if they want to run the tightly integrated tool, via the UI/chat box. For example, the frontend 604 can display A650 a porosity action message with a confirmation question. The user 602 then responds with text that indicates whether they would like to proceed with the workflow. For example, the user 602 can reply A652 “Yes”.

The frontend 604 can submit A654 a command “POST chatContext/: id/messages {message: <message>, metadata: {user: {userConfirmation: true}}}” to the backend 606. The backend 606 can create A656 a new USER message for ChatContext and can return A656 the message id to the frontend 604. The frontend 604 can submit A658 a command “POST chatContext/: id/invoke {chat_message_id: <id>} to the backend 606. The backend 606 can submit A660 the created USER message id and the serialized chat message to the endpoint of the web service, e.g., the handler 607 for yes/no analysis. The handler 607 can route A662 to a yes/no method of the LLM 610. The LLM 610 can perform A664 the yes/no analysis and can send the result to the handler 607. The handler 607 can return A666 a formatted sentiment (yes or no) and related instructions to the backend 606. The backend 606 can create A668 new BOT message with the instructions and the confirmation sentiment. The frontend 604 can display A670 the instructions from the message.

If the user responds that they would like to proceed with the workflow, or if the implementation did not ask the user for confirmation, the frontend 604 then launches the UI workflow corresponding to the tightly integrated tool. For example, the frontend 604 can initiate A670 the porosity workflow. Here, the workflow is a workflow to launch a porosity analysis. The user 602 completes the workflow in the UI and then clicks a button in the UI to submit A672 the completed workflow to the backend 606 for processing. Upon clicking this button, the frontend 604 makes an API call to the backend 606 to submit the workflow for processing. For example, the frontend 604 can submit A674 a “POST runPorosity with ChatContext id” command to the backend 606. The API call includes metadata which indicates that the workflow is part of a tightly integrated tool associated with the unique chat context for the (user_id, project). The API call returns immediately. For example, the backend 606 can trigger A676 a runPorosity task and can return A676 a confirmation indicating that the task has started. The frontend 604 can display A678 the confirmation that the task has started. The frontend 604 enters into a polling loop, e.g., every 10 seconds, waiting for a response from the backend. For example, the frontend 604 can start A697 GET chatContext/: id/messages poll. In some implementations, the response would come over a websocket or synchronous protocol. In some implementations, the polling loop may be faster or slower.

The backend 606 completes the workflow, e.g., the asynchronous workflow 611, as is typical and can otherwise be completed without using the chat or agent. The backend 606 completes A680 the porosity task and sends A680 raw data to the handler 607 to summarize. Upon completing the routine part of the workflow, the backend 606 further continues to process and does the following: “1. The backend creates A680 a project feature, e.g., an entry in the database with the results of the workflow associated with the project. This entry allows the result of the workflow to be passed to future invocations of the agent so that the agent knows the workflow has been run and its results. In some implementations, this entry can be used for different users in future workflows.” “2. The backend creates A680 bookmarks or other UI features on the project to highlight results of the workflow for the user. This gives the user the appearance that the agent has intelligently modified their project as part of the workflow. For example, the backend 606 can create bookmarks of key pores.” “3. The backend summarizes the results of the workflow in plain text/string format and creates a new message in the chat context for the (user_id, project) to be fed back to the agent upon the agent's next invocation.” “4. The backend invokes the agent as before.”

The handler 607 calls A682 a summarize function and return A682 summarized string results to the backend 606. The backend 606 creates A684 TOOL Message with summary as the message content. The backend 606 sends A686 the summary string to the agent 608, e.g., through the handler 607. The handler 607 invokes A688 the agent 608 with observation from porosity.

The agent 608 is initialized and sees the new message, which is the result of the tightly integrated tool, as well as the previous message before the tightly integrated tool message which contains the metadata for the previous instantiation of the agent. The agent re-initializes where it left off with its previous metadata, processes the response from the tightly integrated tool, and is able to continue running another cycle. For example, the agent 608 completes A690 runPorosity and calls A690 the LLM 610 for analysis. The LLM 610 responds A692 with analysis of porosity given the porosity results and the chat/project context.

The agent 608, at this point, may be ready to return a response to the user, run another tightly integrated tool, or run a standard tool. Here, in this diagram, the agent is able to return with a message for the user 602.

The agent 608 returns a response to the backend 606 indicating that it wishes to send a new message to the user with its response. For example, the handler 607 formats A694 a response to allow the backend to create a BOT message. The backend 606 then creates a new message in the chat context with the agent's response. For example, the backend 606 creates A696 a BOT message with a conclusion, a question, or a next action from the agent. The backend 606 returns A698 all messages to the frontend 604.

The frontend 604, in its polling loop, detects A697 that a new message is available and shows A699 it to the user 602.

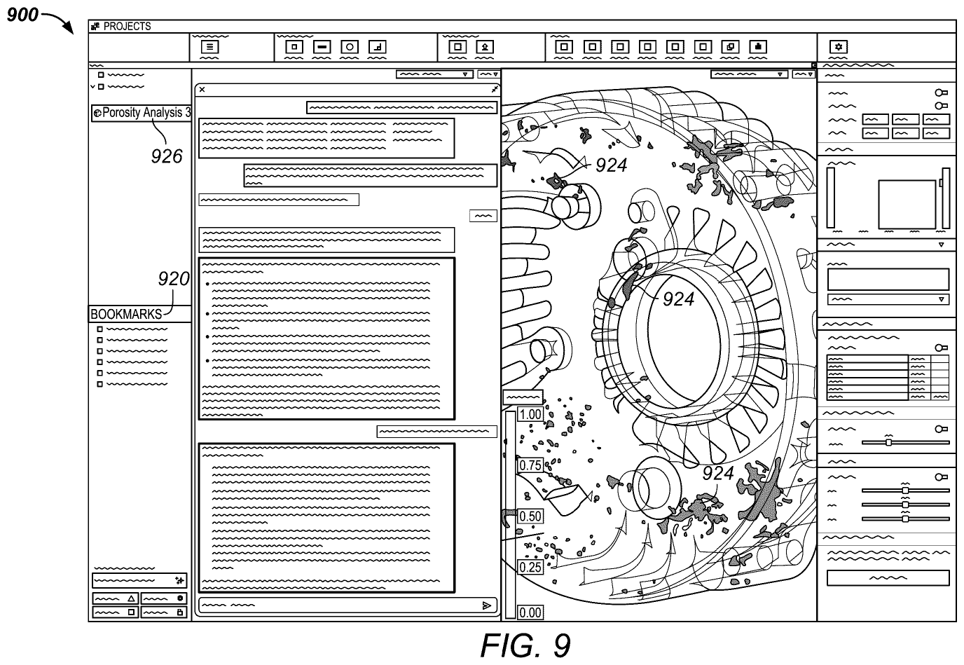

FIG. 9 shows an example user interface 900 of a manufacturing data analysis system. In particular, FIG. 9 shows an example user interface for the example implementation of FIG. 6. Table 5 shows an example conversation between the user and the agent.

TABLE 5
Example conversation between a user and an agent

| | |
|---|---|
| User | “I just got a batch of these parts from a new supplier -- is this one good?” |
| Agent | “To determine the quality of the part, we can analyze it using company X's |
| | software. The software can provide insights into the part's structure, material |
| | properties, and potential defects. However, I'll need more specific information |
| | about what you're looking for. Are you concerned about a specific aspect of the |
| | part such as its dimensions, material consistency, or the presence of defects like |
| | pores or cracks?” |
| User | “This is a die cast aluminum alternator housing -- it needs to withstand some |
| | decent loads applied by the drive belt. The outside looks ok, but I want to know if |
| | there are any defects inside.” |
| Agent | “Shall I launch the porosity analysis workflow to investigate?” |
| User | “Let's do it.” |
| Agent | “To submit a porosity workflow, follow these instructions: In the data panel, |
| | select the volume you want to analyze. Select ‘Porosity’ from the Author panel. |
| | Adjust the threshold until you can clearly see one or more of your pores on the |
| | volume slices.” |
| Agent | “The porosity analysis of your die cast aluminum alternator housing has been |
| | completed. Here are the key findings: |
| | The maximum pore volume is 22.423 mm\hat{ }3, while the minimum is 0.012 |
| | mm\hat{ }3. The average pore volume is 0.556 mm\hat{ }3, with a standard deviation |
| | of 1.916 mm\hat{ }3. This indicates a wide range of pore sizes, which could |
| | potentially affect the part's performance under load. |
| | The sphericity of the pores ranges from 0 (not spherical at all) to 0.950 |
| | (almost perfectly spherical), with an average of 0.545. This suggests that |
| | the pores are generally not very spherical. |
| | The distance of the pores to the surface ranges from 0.317 mm to 5.055 |
| | mm, with an average of 3.093 mm. This means that some pores are quite |
| | close to the surface, which could potentially lead to surface defects or |
| | failure under load. |
| | The total number of pores is 326, and the void volume fraction (the total |
| | volume of the pores divided by the total volume of the part) is 0.001. This |
| | is a relatively low fraction, suggesting that the part is mostly solid. |
| | Given these results, it's important to consider how the part will be used and what |
| | loads it will be subjected to. The presence of pores, especially those close to the |
| | surface, could potentially affect the part's ability to withstand these loads. If the |
| | loads are high and the part is critical to the operation of the system, it may be |
| | worth considering a different manufacturing process or supplier to reduce the |
| | porosity.” |
| User | “What can I do to reduce porosity in this part?” |
| Agent | “To reduce porosity in your die cast aluminum alternator housing, you might |
| | want to consider the following strategies: |
| | 1. Part and Die Design: Ensure that the part and die are well-designed. This |
| | can help reduce porosity to a harmless level. Avoid designing highly |
| | stressed parts with heavy sections and bosses, as they may still give |
| | trouble. Allow for lower tensile strengths in these areas. |
| | 2. Heat Treatment: Avoid heat treatment of parts or use in environment |
| | above 200° C. (400° F.). This can prevent surface blisters caused by |
| | pockets of porosity. |
| | 3. Undercuts: Undercuts cannot be incorporated in simple two-piece dies. If |
| | they are essential, consider using core slides, but be aware that this may |
| | increase the casting price and slow production rates. |
| | 4. Hollow Shapes: Some “hollow” shapes are not readily die-castable due |
| | to the high metal pressures. In special situations, zinc core pieces can be |
| | used and subsequently melted out by heating the casting to 390° C. |
| | (730° F.). |
| | 5. Size Limitations: Consider the size limitations of the die casting |
| | equipment. The current upper limit is about 3000-ton locking pressure, |
| | with a maximum effective area of about 0.77. |
| | By implementing these strategies, you can potentially reduce the porosity in your |
| | part, improving its ability to withstand the loads applied by the drive belt.” |

The software shown is a view into a project. The 3D data 924 is highlighting areas of porosity in the project as a result of running the porosity analysis 926. The bottom three bookmarks in the bookmarks section 920 were created by the agent as described in connection with FIG. 6.

The diagram in FIG. 6 showing an example implementation of using a porosity analysis tool can be applied to other tools. Here is an example implementation when using a CAD comparison tool. The agent launches the CAD comparison workflow in the system and then coaches the user through the step-by-step process of running the analysis, similar to porosity analysis. The backend runs the CAD comparison analysis tool and returns a mesh file, e.g., a polygon file format (PLY) mesh file, an OBJ mesh file, a STL mesh file, that contains a list of coordinates and displacements at those coordinates. The backend can calculate summary statistics as well as percentiles on this data to produce a piece of context that can be passed to the agent.

Embodiments of the subject matter and the functional operations described in this specification can be implemented in digital electronic circuitry, or in computer software, firmware, or hardware, including the structures disclosed in this specification and their structural equivalents, or in combinations of one or more of them. Embodiments of the subject matter described in this specification can be implemented using one or more modules of computer program instructions encoded on a non-transitory computer-readable medium for execution by, or to control the operation of, data processing apparatus. The computer-readable medium can be a manufactured product, such as a hard drive in a computer system or an optical disc sold through retail channels, or an embedded system. The computer-readable medium can be acquired separately and later encoded with the one or more modules of computer program instructions, such as by delivery of the one or more modules of computer program instructions over a wired or wireless network. The computer-readable medium can be a machine-readable storage device, a machine-readable storage substrate, a memory device, or a combination of one or more of them.

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, a runtime environment, or a combination of one or more of them. In addition, the apparatus can employ various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few. Devices suitable for storing computer program instructions and data include all forms of non-volatile memory, media and memory devices, including by way of example semiconductor memory devices, e.g., EPROM (Erasable Programmable Read-Only Memory), EEPROM (Electrically Erasable Programmable Read-Only Memory), and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device 112, e.g., an LCD (liquid crystal display) display device, an OLED (organic light emitting diode) display device, or another monitor, for displaying information to the user, and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input.

The computing system can include clients and servers. A client and server are generally remote from each other and typically interact through a communication network. The relationship of client and server arises by virtue of computer programs running on the respective computers and having a client-server relationship to each other. Embodiments of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described is this specification, or any combination of one or more such back-end, middleware, or front-end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While this specification contains many implementation details, these should not be construed as limitations on the scope of what is being or may be claimed, but rather as descriptions of features specific to particular embodiments of the disclosed subject matter. Further, while the detailed description focuses on the CT scan application context, the described systems and techniques are applicable to other application contexts, such as a mesh, a point cloud, a radiograph, CAD data (e.g., BREP, neural implicit field, signed distance field, level set, parasolid, NURBS, or other CAD format), an image of a part, CAM data (e.g., GCODE), or a PDF drawing.

Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desired results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the invention have been described. Other embodiments are within the scope of the following claims.

What is claimed is:

1. A method comprising:
receiving, by an agent of a manufacturing data analysis system and from a user interface of the manufacturing data analysis system, an input related to manufacturing data;
generating, by the agent, a prompt input based on context information related to the manufacturing data and a task identified for the input;
providing, by the agent, the prompt input to a large language model (LLM);
receiving, by the agent and from the LLM, a response that is based on the prompt input; and
providing, by the agent, the response for display in the user interface.

2. The method of claim 1, wherein the manufacturing data comprises CT scan data for a part.

3. The method of claim 1, wherein the manufacturing data comprises at least one of a mesh, a point cloud, a radiograph, computer aided design (CAD) data, an image, computer aided manufacturing (CAM) data, or a drawing.

4. The method of claim 1, comprising:
receiving, by the agent and from the LLM, a determination based on the prompt input, the determination comprising a tool of the manufacturing data analysis system to be used to process the manufacturing data;
sending, by the agent to a backend of the manufacturing data analysis system, a request to use the tool;
sending, from the backend to a frontend of the manufacturing data analysis system, an instruction to launch the tool in the user interface;
launching, by the frontend, the tool of the manufacturing data analysis system in the user interface;
displaying, by the frontend, in the user interface, an indication of how to use the tool to process the manufacturing data;
calling, by the frontend, a backend application programming interface (API) of the tool; and
processing, by the backend, the manufacturing data using the tool to generate an analysis result; and
receiving, by the agent from the backend, an indication that the using of the tool is completed and the analysis result.

5. The method of claim 4, further comprising:
generating a second prompt input based on the analysis result;
providing the second prompt input to the LLM;
receiving, from the LLM, interpretation data of the analysis result; and
displaying the interpretation data of the analysis result in the user interface.

6. The method of claim 4, comprising:
after displaying in the user interface, the indication of how to use the tool, receiving, by the frontend, a user input from the user interface of the manufacturing data analysis system; and
calling, by the frontend, the backend API of the tool by providing the user input as an input to the backend API of the tool.

7. The method of claim 4, wherein the determination of the tool of the manufacturing data analysis system to be used to process the manufacturing data is based on available tools of the manufacturing data analysis system and a data type of the manufacturing data.

8. The method of claim 7, comprising:
modifying, by the agent, the available tools based on one or more types of data in the manufacturing data and/or one or more types of analysis the manufacturing data analysis system is configured to run.

9. The method of claim 4, wherein the agent is a stateless agent that (i) interacts with the LLM and the backend of the manufacturing data analysis system, and (ii) is deployed and updated independently from the backend of the manufacturing data analysis system.

10. The method of claim 9, comprising:
after receiving the determination of the tool to be used to process the manufacturing data, determining, by the stateless agent, that the tool requires a user input;
in response to determining that the tool requires the user input, exiting, by the stateless agent, a current process and sending to the backend a signal comprising: (i) the request to use the tool, and (ii) state metadata for the stateless agent, wherein the backend of the manufacturing data analysis system instructs the frontend of the manufacturing data analysis system to launch the tool and to receive the user input and generates the analysis result of the manufacturing data after receiving the user input, wherein the state metadata is stored across two or more API calls to one or more tools of the manufacturing data analysis system;
relaunching the stateless agent after receiving the analysis result of the manufacturing data from the backend;
initializing the stateless agent using the state metadata; and
processing, by the stateless agent, the analysis result of the manufacturing data using the LLM.

11. The method of claim 1, wherein the input comprises a question related to (1) designing or manufacturing a part, or (2) using the manufacturing data analysis system based on one or more projects, the method comprises:
invoking, by the agent, a tool to obtain an answer to the question;
generating, by the agent, the prompt input based on the context information and the answer to the question;
providing, by the agent, the prompt input to the LLM;
receiving, by the agent and from the LLM, a response to the question that summarizes the answer to the question based on the context information; and
providing, by the agent and in the user interface, the response to the question.

12. The method of claim 11, wherein the tool comprises a vectorstore tool storing embedding data and performing vector search, wherein the embedding data comprises embedding vectors of at least one of design and manufacturing documentation, user interface documentation, CT scanning documentation, or user-specific documentation, wherein invoking, by the agent, the tool to obtain the answer to the question comprises calling, by the agent, an API of the vectorstore tool to retrieve one or more pieces of text related to the question by searching in the embedding data using a similarity metric.

13. The method of claim 12, wherein the user-specific documentation comprises historical chat exchanges from users within an organization, structured institutional knowledge, or a combination of both.

14. The method of claim 1, wherein the manufacturing data is related to one or more projects, the method comprises:
determining project information of the one or more projects based on token limits and/or memory constraints; and
generating the prompt input based on the context information and the project information.

15. The method of claim 14, wherein the manufacturing data of the one or more projects comprises CT scan data for a part, wherein the project information comprises scan information of the CT scan data, wherein the scan information comprises scan name data, scan setting data, and one or more predictions generated using a machine learning algorithm based on the CT scan data, wherein the one or more predictions comprises data indicating whether the CT scan data has a defect, a number of materials in the CT scan data, whether motion is found in the CT scan data, or labels of contents of the part.

16. The method of claim 1, comprising:
obtaining, by the agent, chat history information with a user comprising one or more previous inputs received from the user at the user interface of the manufacturing data analysis system and corresponding outputs previously provided at the user interface to the user; and
generating, by the agent, the prompt input based on the context information and the chat history information.

17. The method of claim 16, wherein the chat history information with the user is saved in a queryable vectorstore.

18. The method of claim 16, comprising:
determining a maximum size of the chat history information; and
obtaining, by the agent, the chat history information with a size that is not larger than the maximum size to save bandwidth usage and processing resource usage.

19. The method of claim 16, comprising:
generating, by the agent, an initial prompt input based on the chat history information;
providing, by the agent, the initial prompt input to the LLM;
receiving, by the agent and from the LLM, a summary of the chat history information based on the initial prompt input, wherein a size of the summary of the chat history information is smaller than a size of the chat history information; and
generating, by the agent, the prompt input based on the context information and the summary of the chat history information.

20. The method of claim 1, wherein generating the prompt input comprises generating the prompt input based on the context information and description information of a tool of the manufacturing data analysis system.

21. The method of claim 1, wherein the manufacturing data analysis system comprises a CT scanner system, the user interface is a user interface of the CT scanner system.

22. A manufacturing data analysis system comprising:
a frontend comprising a user interface;
a backend of the manufacturing data analysis system;
one or more tools of the manufacturing data analysis system accessible through application programming interface (API) calls;
an agent that interacts with a large language model (LLM) and the backend of the manufacturing data analysis system;
a data processing apparatus including at least one hardware processor; and
a non-transitory computer-readable medium encoding instructions configured to cause the data processing apparatus to perform operations comprising:
receiving, by the agent and from the user interface, an input related to manufacturing data;
generating, by the agent, a prompt input based on context information related to the manufacturing data and a task identified for the input;
providing, by the agent, the prompt input to a large language model (LLM);
receiving, by the agent and from the LLM, a response that is based on the prompt input; and
providing, by the agent, the response for display in the user interface.

23. A non-transitory computer-readable medium encoding instructions operable to cause data processing apparatus to perform operations comprising:
receiving, by an agent of a manufacturing data analysis system and from a user interface of the manufacturing data analysis system, an input related to manufacturing data;
generating, by the agent, a prompt input based on context information related to the manufacturing data and a task identified for the input;
providing, by the agent, the prompt input to a large language model (LLM);
receiving, by the agent and from the LLM, a response that is based on the prompt input; and
providing, by the agent, the response for display in the user interface.
